(19) United States
(12) Patent Application Publication
(10) Pub. No.: US 2025/0136392 A1
(43) Pub. Date: May 1, 2025

(54) DEVICE TRANSFER APPARATUS USING PLURALITY OF VIBRATION SOURCES AND METHOD OF CONTROLLING THE SAME

(71) Applicant: CHUNG ANG University Industry Academic Cooperation Foundation, Seoul (KR)

(72) Inventors: Jaesoo YOO, Seoul (KR); Yongtae Ko, Gyeonggi-do (KR)

(73) Assignee: CHUNG ANG University Industry Academic Cooperation Foundation, Seoul (KR)

(21) Appl. No.: 18/781,346

(22) Filed: Jul. 23, 2024

(30) Foreign Application Priority Data
Oct. 27, 2023 (KR) 10-2023-0145966
Mar. 21, 2024 (KR) 10-2024-0039206

(51) Int. Cl. B65G 54/00; H01L 21/67

(52) U.S. Cl. CPC B65G 54/00; H01L 21/67121

(57) ABSTRACT

A device transfer apparatus is provided. The device transfer apparatus includes a container of a polygonal shape which contains a substrate including device holes, vibration sources which generates vibration and transfers the vibration to a fluid in the container, and a processor which controls outputs of the vibration sources. The vibration sources include first group vibration sources arranged on a circumference of a first circle having a radius of a first distance from a central point, and second group vibration sources arranged on a circumference of a second circle which is concentric with the first circle and has a radius of a second distance that is longer than the first distance. The container is arranged on the central point and contains a fluid and micro devices distributed in the fluid. The processor controls the first group vibration sources and the second group vibration sources to output vibration.

### CROSS-REFERENCE TO RELATED APPLICATIONS

This application is based on and claims priority under 35 U.S.C. § 119 to Korean Patent Application No. 10-2023-0145966, filed on Oct. 27, 2023, and Korean Patent Application No. 10-2024-0039206, filed on Mar. 21, 2024, in the Korean Intellectual Property Office, the disclosures of which are incorporated by reference herein in their entireties.

### BACKGROUND

### 1. Field

The disclosure relate to a device transfer apparatus that transfers a micro device to a substrate using a plurality of vibration sources and a method of controlling the device transfer apparatus. Embodiments may be applied to mass transfer technology using self-arranging fine functional semiconductor chips. Also, the self-arranging fine functional semiconductor chips may be widely applied from a human biology field to a display field. Also, the embodiments may be used to classify and aggregate the self-arranging fine functional semiconductor chips at desired positions and arrange the same in desired patterns.

This study is conducted with support from the Samsung Future Technology Promotion Project (Assignment number: SRFC-IT2201-02).

### 2. Description of the Related Art

There is a growing demand for the development of technology that may artificially control operations of micro devices in the field of displays and micro-structured semiconductor fields, such as micro-electro mechanical systems (MEMS). Also, the field of biochemistry also has a growing demand for the development of technology that may artificially control movements of multiple cell-level particles. Moreover, particles or elements used in the various fields inevitably tend to become increasingly smaller in size due to technological development.

In order to artificially control the fine particles to suit their purposes, research and development has been conducted in various academic fields. The control technology for fine particles, requires effects, such as reduction of required power, non-destructive properties of devices, and prevention of impurity contamination. Due to this, technology using sound, which requires less power than optical technology by one hundred thousandth, is being studied.

Although the technology using sound may move fine devices, chips, and so on, it is difficult to apply the technology to an environment where multiple devices are moved on a large substrate.

### SUMMARY

Additional aspects will be set forth in part in the description which follows and, in part, will be apparent from the description, or may be learned by practice of the presented embodiments of the disclosure.

According to an aspect of the disclosure, a device transfer apparatus is provided. The device transfer apparatus includes a container of a polygonal shape configured to contain a substrate including a plurality of device holes, a plurality of vibration sources configured to generate vibration and transfer the vibration to a fluid in the container, and a processor configured to control outputs of the plurality of vibration sources. The plurality of vibration sources include at least one first group vibration source arranged on a circumference of a first circle having a radius of a first distance from a central point, and at least one second group vibration source arranged on a circumference of a second circle which is concentric with the first circle and has a radius of a second distance that is longer than the first distance, the container is arranged on the central point and contains a fluid and micro devices distributed in the fluid, and the processor is further configured to control at least one of the at least one first group vibration source and the at least one second group vibration source to output vibration of an output frequency.

Also, according to one embodiment, the at least one first group vibration source may include at least one pair of first group vibration sources arranged on at least one short axis passing through the central point and facing each other about the central point, and the at least one second group vibration source may include at least one pair of second group vibration sources arranged on at least one long axis passing through the central point and facing each other about the central point.

Also, according to one embodiment, the at least one short axis and the at least one long axis may be arranged alternately at equal angular intervals.

Also, according to one embodiment, the at least one short axis may include a first short axis and a second short axis, the at least one long axis may include a first long axis and a second long axis, and the at least one short axis and the at least one long axis may be arranged at intervals of 45 degrees in an order of the first short axis, the first long axis, the second short axis, and the second long axis.

Also, according to one embodiment, the container may have an octagonal shape, and each of the at least one short axis and the at least one long axis may be arranged to correspond to each corner of the octagonal shape of the container.

Also, according to one embodiment, a pair of first group vibration sources facing each other may output vibrations of a same frequency, and a pair of second group vibration sources facing each other may output vibrations of a same frequency.

Also, according to one embodiment, the processor may be further configured to obtain a first image of the substrate in the container, and control the plurality of vibration sources in at least one of a plurality of operation modes in which a predefined output frequency is output through at least one vibration source among the plurality of vibration sources, based on the first image.

Also, according to one embodiment, the processor may be further configured to control the plurality of vibration sources to sequentially operate in two or more operation modes among the plurality of operation modes.

Also, according to one embodiment, the processor may be further configured to determine, based on the first image, a transfer state in which the micro devices are transferred into a plurality of device holes of the substrate and positions of remaining micro devices that are not transferred to the substrate, and control the plurality of vibration sources to operate in at least one operation mode among the plurality of operation modes based on the transfer state and the positions of the remaining micro devices.

Also, according to one embodiment, the processor may be further configured to control the plurality of vibration sources to operate for a reference time in at least one of the plurality of operation modes and repeat a cycle of obtaining the first image.

Also, according to one embodiment, the processor may be further configured to determine a transfer rate, which is a ratio of the plurality of device holes into which the micro devices are transferred, and when the transfer rate reaches a target transfer rate, the processor is further configured to control the plurality of vibration sources and stop the cycle of obtaining the first image.

Also, according to one embodiment, the plurality of operation modes may include at least one of a first mode in which a pair of vibration sources on a first short axis among the at least first group vibration source vibrate at a first frequency and a pair of vibration sources on a second short axis among the at least one first group vibration source vibrate at a second frequency that is higher than the first frequency by a first beat frequency, a second mode in which a pair of vibration sources on a first long axis among the at least second group vibration source vibrate at a third frequency and a pair of vibration sources on a second long axis among the at least one second group vibration source vibrate at a fourth frequency that is higher than the third frequency by the first beat frequency, a third mode in which the pair of vibration sources on the first short axis among the at least first group vibration source vibrate at the first frequency, the pair of vibration sources on the second short axis among the at least one first group vibration source vibrate at the second frequency, the pair of vibration sources on the first long axis among the at least second group vibration source vibrate at the third frequency, and the pair of vibration sources on the second long axis among the at least one second group vibration source vibrate at the fourth frequency, a fourth mode in which the pair of vibration sources on the first short axis among the at least first group vibration source vibrate at the second frequency and the pair of vibration sources on the second short axis among the at least one first group vibration source vibrate at the first frequency, a seventh mode in which the pair of vibration sources on the first short axis among the at least first group vibration source vibrate at the first frequency and the pair of vibration sources on the second short axis among the at least one first group vibration source vibrate at a fifth frequency that is higher than the first frequency by a second beat frequency, an eleventh mode in which the pair of vibration sources on the first short axis among the at least first group vibration source vibrate at the fifth frequency and the pair of vibration sources on the second short axis among the at least one first group vibration source vibrate at the first frequency, a fourteenth mode in which the pair of vibration sources on the first short axis among the at least first group vibration source vibrate at the first frequency and the pair of vibration sources on the second short axis among the at least one first group vibration source vibrate at a sixth frequency that is higher than the first frequency by a third beat frequency, a fifteenth mode in which the pair of vibration sources on the first short axis among the at least first group vibration source vibrate at the sixth frequency and the pair of vibration sources on the second short axis among the at least one first group vibration source vibrate at the first frequency, a first switch mode in which the pair of vibration sources on the first short axis among the at least first group vibration source vibrate at the first frequency, a second switch mode in which the pair of vibration sources on the second short axis among the at least first group vibration source vibrate at the first frequency, a third switch mode in which the pair of vibration sources on the first long axis among the at least second group vibration source vibrate at the first frequency and a signal amplification rate is set differently between two vibration sources of the pair of vibration sources on the first long axis, and a fourth switch mode in which the pair of vibration sources on the first short axis among the at least first group vibration source vibrate at the first frequency, and vibration sources in one group among a third group vibration sources and a fourth group vibration sources, which are divided by the first short axis, vibrate at the first frequency, the second beat frequency may be thrice the first beat frequency, and the third bit frequency may be five times the first bit frequency.

Also, according to one embodiment, the plurality of operation modes may include at least one of a first sequential mode shift (SMS) mode for operating in the first mode and then operating in the second mode, a second SMS mode for operating in the third mode, a third SMS mode for operating in the first mode and then operating in the fourth mode, a fourth SMS mode for operating in the seventh mode and then operating in the eleventh mode, a fifth SMS mode for operating in an order of the first mode, the first switch mode, the second mode, and the second switch mode, a sixth SMS mode for operating in an order of the third mode, the first switch mode, the third mode, and the second switch mode, a seventh SMS mode for operating in an order of the first mode, the first switch mode, the fourth mode, and the second switch mode, an eighth SMS mode for operating in an order of the seventh mode, the first switch mode, the eleventh mode, and the second switch mode, a ninth SMS mode for operating in an order of the fourteenth mode, the first switch mode, the fifteenth mode, and the second switch mode, a tenth SMS mode for operating in an order of the seventh mode, the first switch mode, the eleventh mode, the second switch mode, and the third switch mode, and an eleventh SMS mode for operating in an order of the seventh mode, the first switch mode, the eleventh mode, the second switch mode, and the fourth switch mode.

Also, according to one embodiment, the first beat frequency, the second beat frequency, and the third beat frequency may each be about 1 Hz to about 30 Hz.

Also, according to one embodiment, vibrations generated by the plurality of vibration sources may have frequencies in a range of about 20 Hz to about 500 Hz.

Also, according to one embodiment, the device transfer apparatus may further include a plurality of connection plates respectively connecting the container to the plurality of vibration sources.

Also, according to one embodiment, each of the plurality of connection plates may have a length of about 2 cm to about 20 cm.

Also, according to one embodiment, a length difference between the first distance and the second distance may be 3 cm or more and 30 cm or less.

Also, according to one embodiment, the device transfer apparatus may further include a camera configured to capture an image of the substrate in the container, wherein the processor may be further configured to determine a transfer state in which the micro devices are transferred into the plurality of device holes of the substrate based on an image captured by the camera and determine an operation mode of the at least one first group vibration source or the at least one second group vibration source based on the determined transfer state.

According to another aspect of the disclosure, a method of controlling a device transfer apparatus is provided. The method of controlling a device transfer apparatus includes obtaining a captured image of a substrate in a container of a polygonal shape containing the substrate including a plurality of device holes, determining a transfer state in which micro devices are transferred into the plurality of device holes of the substrate based on the captured image, determining, based on the determined transfer state, an output frequency output from at least one first group vibration source or at least one second group vibration source, which is configured to transfer vibration to a fluid in the container, outputting the output frequency from at least one of the at least one first group vibration source and the at least one second group vibration source, and re-obtaining the captured image after the output of the output frequency is completed, and determining whether the transfer state has reached a target transfer rate based on the re-obtained captured image. Also, when the transfer state has not reached the target transfer rate, the determining of the transfer state, the determining of the output frequency, the outputting of the output frequency, and the determining whether the transfer state has reached the target transfer rate are repeated, the device transfer apparatus includes a plurality of vibration sources configured to generate vibration and transfer the vibration to a fluid in the container, and the plurality of vibration sources include the at least one first group vibration source on a circumference of a first circle having a radius of a first distance from a central point, and the at least one second group vibration source on a circumference of a second circle which has a radius of a second distance that is longer than the first distance and is concentric with the first circle, and the container is on the central point.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram illustrating a structure of a device transfer apparatus according to an embodiment;

FIG. 2 is a diagram illustrating a structure of a device transfer apparatus according to an embodiment;

FIG. 3 is a diagram illustrating a substrate and micro devices in a container according to an embodiment;

FIG. 4 is a diagram illustrating a container and a plurality of vibration sources according to an embodiment;

FIGS. 5A, 5B, and 5C are views illustrating a structure of a micro device according to an embodiment;

FIG. 6 is a diagram illustrating a structure of a device transfer apparatus according to an embodiment;

FIG. 7 is a diagram illustrating a method of controlling a device transfer apparatus, according to an embodiment;

FIG. 8 is a diagram illustrating an arrangement of a plurality of vibration sources according to an embodiment;

FIG. 9 is a diagram illustrating definitions of a plurality of operation modes according to an embodiment;

FIG. 10 is a diagram illustrating a plurality of operation modes according to an embodiment;

FIG. 11 is a diagram illustrating an operation of a first sequential mode shift (SMS) mode according to an embodiment;

FIG. 12 is a diagram illustrating an operation of a second SMS mode according to an embodiment;

FIG. 13 is a diagram illustrating an operation of a third SMS mode according to an embodiment;

FIG. 14 is a diagram illustrating an operation of a fourth SMS mode according to an embodiment;

FIG. 15 is a diagram illustrating an operation of a fifth SMS mode according to an embodiment;

FIG. 16 is a diagram illustrating an operation of a sixth SMS mode according to an embodiment;

FIG. 17 is a diagram illustrating an operation of a seventh SMS mode according to an embodiment;

FIG. 18 is a diagram illustrating an operation of an eighth SMS mode according to an embodiment;

FIG. 19 is a diagram illustrating an operation of a ninth SMS mode according to an embodiment;

FIG. 20 is a diagram illustrating an operation of a tenth SMS mode according to an embodiment;

FIG. 21 is a diagram illustrating an operation of an eleventh SMS mode according to an embodiment;

FIG. 22 is a diagram illustrating a self-assembly ratio according to an SMS mode according to an embodiment;

FIG. 23 illustrates images of movement of micro devices captured while applying a standing wave of 66 Hz, according to an embodiment;

FIG. 24 illustrates images of movement of micro devices captured while applying a first beat frequency, according to an embodiment;

FIG. 25 illustrates images of movement of micro devices captured while applying a second beat frequency, according to an embodiment;

FIG. 26 illustrates captured images of a result of arraying micro devices, according to an embodiment;

FIG. 27 illustrates images of states in which a first mode and a second mode are sequentially performed, according to an embodiment;

FIG. 28 illustrates images of states in which a first switch mode, a third mode, and a first mode are sequentially performed, according to an embodiment; and

FIG. 29 illustrates images of states in which a second mode, a second switch mode, and a third mode are sequentially performed, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

The disclosure clarifies the scope of the claims of the disclosure, and explains the principles of the embodiments such that those skilled in the art may practice the embodiments, and discloses embodiments. The disclosed embodiments may be implemented in various forms.

Like reference numerals refer to like components throughout the disclosure. The disclosure does not describe all components of the embodiments, and general content or overlapping content between the embodiments in the technical field to which the embodiments pertain is omitted. The term “part or portion” used in the specification may be implemented by software or hardware, and a plurality of “portions” may be implemented by a single component (a unit or an element) depending on embodiments, or a single “portion” may also include a plurality of components. Hereinafter, embodiments and operating principles thereof will be described with reference to the attached drawings.

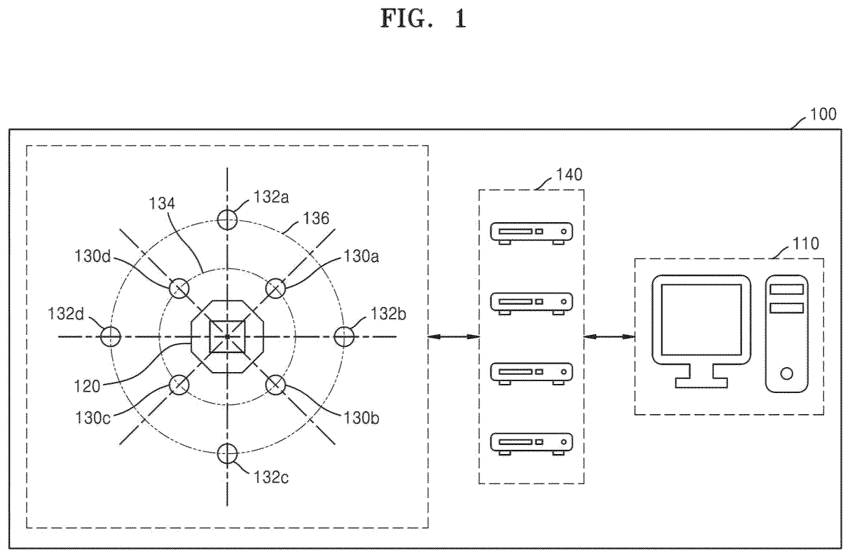

FIG. 1 is a diagram illustrating a structure of a device transfer apparatus according to an embodiment.

A device transfer apparatus 100 according to an embodiment includes a container 120 and a plurality of vibration sources 130a, 130b, 130c, 130d, 132a, 132b, 132c, and 132d. In the disclosure, the plurality of vibration sources 130a, 130b, 130c, 130d, 132a, 132b, 132c, and 132d are collectively referred to as an identification number 130.

The plurality of vibration sources 130 may be connected to the container 120 through a preset connection plate. The plurality of vibration sources 130 may each output vibration of a preset frequency, and the vibration output from the plurality of vibration sources 130 may be transferred to the container 120 through the connection plate.

The plurality of vibration sources 130 are controlled by a computing device 110 including a processor. The computing device 110 may output a control signal to the plurality of vibration sources 130 to control at least one of turn-on/off, an output frequency, a phase, timing, or vibration intensity of each of the plurality of vibration sources 130. The computing device 110 may determine an output frequency of the plurality of vibration sources 130 by using a preset computer program and data and control the plurality of vibration sources 130 such that the determined output frequency is output through the plurality of vibration sources 130.

The plurality of vibration sources 130 may generate and output vibration based on a signal output from a signal amplifier 140. The signal amplifier 140 may generate and output a waveform signal corresponding to the output frequency by using a control signal output from the computing device 110. The plurality of vibration sources 130 may receive the waveform signal corresponding to the output frequency from the signal amplifier 140 and generate and output vibration corresponding to the output frequency.

The container 120 has a polygonal shape. The container 120 may have, for example, an octagonal shape. Also, the container 120 may have, for example, a regular polygonal shape or a regular octagonal shape.

The container 120 has a fluid-containing structure capable of containing a fluid. The fluid containing structure may be implemented, for example, in the form of a partition wall having a space for containing a fluid on an upper surface of the container 120. The fluid containing structure may correspond to chunk. The fluid may correspond to, for example, ethanol.

The substrate includes device holes for fixing micro devices. The device holes may be arranged in a preset pattern. For example, the device holes may be arranged in a two-dimensional array. A pattern of the device holes may be determined to correspond to a pattern in which the micro devices are arranged on the substrate to be manufactured.

The device holes have shapes corresponding to shapes of the micro devices. Also, each of the device holes is formed to have a step difference from an upper surface of the container 120 to accommodate the micro device, and is formed in a concave shape. According to one embodiment, the micro device has an asymmetric shape. When the micro device has an asymmetric shape, the device hole also has an asymmetric shape corresponding to the micro device.

According to one embodiment, the plurality of vibration sources 130 are arranged on a plurality of concentric circles 134 and 136. The number of concentric circles 130 may be determined in various ways depending on embodiments. According to one embodiment, the plurality of concentric circles 130 may include a first circle 134 and a second circle 136. The first circle 134 has a smaller radius than the second circle 136. Also, the plurality of vibration sources 130 may be arranged to correspond to respective sides of the container 120 of a polygonal shape. For example, the container 120 may have a regular octagon shape, and eight vibration sources 130 may be arranged to correspond to respective sides of the regular octagon. The container 120 may be in the center of the plurality of concentric circles 130.

The plurality of vibration sources 130 include first group vibration sources 130a, 130b, 130c, and 130d arranged on the first circle 134, and second group vibration sources 132a, 132b, 132c, and 132d arranged on the second circle 136. The first group vibration sources 130a, 130b, 130c, and 130d include a plurality of vibration sources arranged on the first circle 134. The second group vibration sources 132a, 132b, 132c, and 132d include a plurality of vibration sources arranged on the second circle 136.

The computing device 110 may control one or a combination of the first group vibration sources 130a, 130b, 130c, and 130d or the second group vibration sources 132a, 132b, 132c, and 132d to output vibration of a preset output frequency. in order for the computing device 110 to move a micro device in a desired direction or pattern, the computing device 110 may determine an output frequency of the first group vibration sources 130a, 130b, 130c, and 130d or the second group vibration sources 132a, 132b, 132c, and 132d and may output vibration of the determined output frequency through at least one of the first group vibration sources 130a, 130b, 130c, and 130d or the second group vibration sources 132a, 132b, 132c, and 132d).

By outputting the vibration of the output frequency through the first group vibration sources 130a, 130b, 130c, and 130d and the second group vibration sources 132a, 132b, 132c, and 132d, the vibration output from the plurality of vibration sources 130 are transferred to the container 120 through the connection plate and to a fluid in the container 120. As the vibration is transferred to the fluid, a micro device in the fluid is moved in a preset direction or pattern due to the vibration. The micro devices are distributed along a nodal line of a wave generated in the fluid by the vibration. In the disclosure, vibration is applied to each side of the container 120 of a polygonal shape. By combining the resulting vibrations, micro devices may be dispersed in a desired pattern in the fluid. Therefore, the device transfer apparatus 100 according to an embodiment has an effect of finely controlling the movement of a micro device by combining vibrations output through the plurality of vibration sources 130.

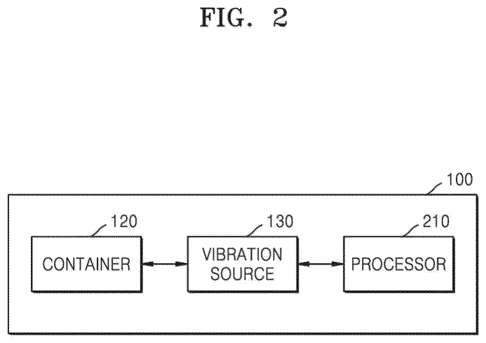

FIG. 2 is a diagram illustrating a structure of a device transfer apparatus according to an embodiment.

According to the embodiment, the device transfer apparatus 100 includes a container 120, a vibration source 130, and a processor 210. The container 120 receives the vibration output from the vibration source 130.

The container 120 may be connected to the vibration source 130 by a connection plate and receive the vibration output from the vibration source 130 through the connection plate. As described above, the container 120 may have a polygonal shape, for example, a regular octagon. The container 120 contains a substrate and a fluid. The container 120 may contain many micro devices distributed in a fluid.

The vibration source 130 is around the container 120. The vibration source 130 may include the plurality of vibration sources 130. The plurality of vibration sources 130 are arranged on a plurality of concentric circles. The container 120 is in the center of the concentric circle. The plurality of vibration sources 130 may include first group of vibration sources 130a, 130b, 130c, and 130d arranged on the first circle 134 and second group vibration sources 132a, 132b, 132c, and 132d arranged on the second circle 136. The second circle 136 has a longer radius than the first circle 134.

According to an embodiment, a radius difference between the first circle 134 and the second circle 136 may be set to be 3 cm or more and 30 cm or less. When the radius difference between the first concentric circle and the second concentric circle is less than 3 cm, while vibration is transferred from the vibration source 130 and wave energy is transferred to the container 120 in which a fluid is contained, it is difficult to induce a vortex by a mutual frequency difference, that is, a beat frequency. Also, when the radius difference between the first and second concentric circles is more than 30 cm, it is difficult to drive the device transfer apparatus 100 due to a structure of the device transfer apparatus 100 in terms of a weight and durability of the vibration source 130. Therefore, according to an embodiment, the radius difference between the first and second concentric circles is set to a range of 3 cm to 30 cm, and thus, there is an effect of increasing vibration transmission performance and durability of the device transfer apparatus 100.

The plurality of vibration sources 130 form waves in the fluid in the container 120. According to an embodiment, the plurality of vibration sources 130 may generate a standing wave by outputting vibration from a pair of opposing vibration sources. Whether the standing wave is formed depends on an applied pulse signal and a boundary condition of a substrate by which a waveform is generated. Waveforms generated in a fluid in the container 120 may be changed depending on boundary conditions. This is related to an eigen value, and a standing wave is formed in the container 120 when a composite wave has the eigen value of a vibration signal. Vibration energy applied to a micro device as an external force is transferred by changing a position of a nodal line of vibration. That is, micro devices are gathered in a place where a pressure is lower, and the plurality of vibration sources 130 change a position of the nodal line to induce movement of the micro devices gathered in the place where the pressure is lower. A change in the nodal line may be induced by generating the composite wave by using the plurality of vibration sources 130.

According to one embodiment, the plurality of vibration sources 130 may include at least one of an actuator, a lead zirconate titanate (PZT) transducer, and a speaker. The plurality of vibration sources 130 may generate and output standing waves with an output frequency.

According to an embodiment, the plurality of vibration sources 130 may output vibrations with an output frequency ranging from 10 Hz to 500 Hz. According to an embodiment, the plurality of vibration sources 130 may generate and output acoustic waves.

The processor 210 controls all operations of the device transfer apparatus 100. The processor 210 may include a plurality of processors. The processor 210 may perform a preset operation by executing instructions or commands stored in a memory (not illustrated). Also, the processor 210 controls operations of components included in the device transfer apparatus 100.

The processor 210 may include a plurality of processors as a configuration for controlling a series of processes such that the device transfer apparatus 100 according to an embodiment to be described below operates. The plurality of processors included in the processor 210 may include a circuitry, such as a system on chip (SoC) and integrated circuit (IC). The plurality of processors included in the processor 210 may include a general-purpose processor, such as a central processing unit (CPU), a microprocessor unit (MPU), an application processor (AP), or a digital signal processor (DSP), a dedicated processor for graphics, such as a graphics processing unit (GPU) or a vision processing unit (VPU), a dedicated processor for artificial intelligence, such as a neural processing unit (NPU), or a dedicated processor for communication, such as a communication processor (CP). When the plurality of processors included in the processor 210 are dedicated processors for artificial intelligence, the dedicated processors for artificial intelligence may be designed with a hardware structure specialized for processing a specific artificial intelligence model.

The processor 210 may write data to a memory and read the data stored in the memory, and in particular, may process data according to a predefined operation rule or artificial intelligence model by executing a program stored in a memory or at least one instruction. Accordingly, the processor 210 may perform operations to be described in following embodiments, and in subsequent embodiments, operations to be performed by the device transfer device 100 or detailed components included in the device transfer device 100 may be regarded as operations that are performed by the processor 210 unless otherwise specified.

The processor 210 may generate and output a drive signal to the plurality of vibration sources 130. The drive signal may be output to the plurality of vibration sources 130. According to an embodiment, the drive signal may be output to the signal amplifier 140, and the signal amplifier 140 may output the amplified drive signal to the plurality of vibration sources 130. The processor 210 may generate a pulse signal for controlling a waveform of vibration energy of the plurality of vibration sources 130. The processor 210 may generate the pulse signal by using a preset function generator.

The processor 210 may control an operation of a micro device by adjusting frequencies of standing waves output from the plurality of vibration sources 130. The processor 210 may set a target movement path of the micro device and control the plurality of vibration sources 130 such that the micro device is moved to the target movement path.

The container 120 is replaceable from the device transfer apparatus 100. According to an embodiment, the container 120 may be replaced with various containers 120 of different specifications or sizes. The container 120 may also be a disposable container. The container 120 may have a fixed structure for fixing a substrate.

The plurality of vibration sources 130 may be arranged in a predefined arrangement in a preset support structure. The plurality of vibration sources 130 may be arranged on a plurality of concentric circles in the support structure. The support structure may have a structure for fixing the container 120 at the center of a concentric circle.

The processor 210 may be electrically connected to the plurality of vibration sources 130. According to an embodiment, the processor 210 may be formed integrally with the plurality of vibration sources 130. Also, according to an embodiment, the processor 210 may be in a preset external device electrically connected to the plurality of vibration sources 130. The external device may correspond to an electronic device, such as a computer, a tablet personal computer (PC), a laptop computer, or a communication terminal.

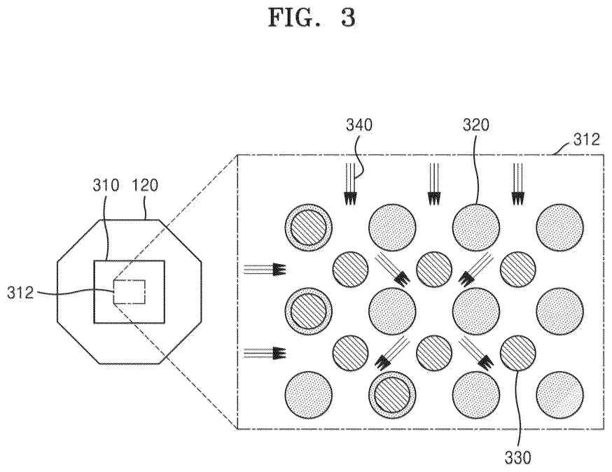

FIG. 3 is a diagram illustrating a substrate and micro devices arranged in a container according to an embodiment.

FIG. 3 illustrates a state in which a first region 312 of a substrate 310 fixed to the container 120 is enlarged.

According to an embodiment, the container 120 may contain the substrate 310. The container 120 has a preset fixed structure, and the substrate 310 may be fixed to the container 120 by the fixed structure. An embodiment may provide a cartridge shape in which the container 120 is formed integrally with the substrate 310. When a micro device is completely transferred to a cartridge, the cartridge may transfer the micro device to another preset substrate.

The substrate 310 includes a plurality of device holes 320 in which micro devices 330 may be accommodated and fixed thereto. The plurality of device holes 320 are engraved in a surface of the substrate 310. The plurality of device holes 320 may be formed in shapes corresponding to the micro devices 330 to safely place or fix the micro devices 330. The plurality of device holes 320 may be formed on the substrate 310 in a preset two-dimensional array. According to an embodiment, when the micro device 330 is a mini-light emitting diode (Mini-LED) with a size of 70 μm or more, the substrate 310 may have a structure in which an elastic film is placed on a glass substrate and a fine metal mesh (FMM) is placed thereon. Also, according to an embodiment, when the micro device 330 corresponds to a micro LED, the substrate 310 may have a structure in which an engraved pattern is formed directly in a silicon substrate.

FIG. 3 illustrates that the first region 312 of the substrate 310 is enlarged and illustrated on the right. An operation of the micro device 330 will be described with reference to the enlarged drawing of the first region 312.

When vibration energy is output from the plurality of vibration sources 130, the vibration energy is transferred to the container 120, and force 340 is applied to the micro device 330 in a fluid. The micro device 330 is moved to the device hole 320 of the substrate 310 by the force and direction applied to the micro device 330 due to the vibration energy and is safely placed in the device hole 320 that matches a shape of the micro device 330. The micro device 330 may move or rotate by the force 340 applied by vibration energy.

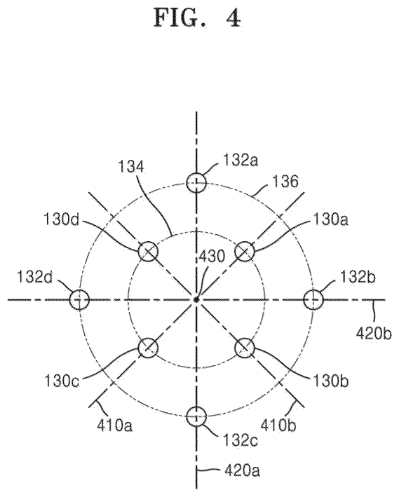

FIG. 4 is a diagram illustrating a container and a plurality of vibration sources according to an embodiment.

In the disclosure, descriptions are focused on an embodiment in which four vibration sources are arranged in each of two concentric circles. also, in the disclosure, descriptions are focused on an embodiment in which eight vibration sources 130 are arranged to correspond to corners of the container 120 having a regular octagonal shape. However, the number of concentric circles and the number of vibration sources may be changed and are not limited to the descriptions of the embodiments.

According to an embodiment, the plurality of vibration sources 130 may be arranged on the plurality of concentric circles including first and second concentric circles 134 and 136. The plurality of concentric circles 134 and 136 are circles centered on the same central point 430 and having different radii. The first circle 134 may have a radius of a first distance, and the second circle 136 may have a radius of a second distance.

The plurality of vibration sources 130 include the first group vibration sources 130a, 130b, 130c arranged on the first circle 134, and 130d and the second group vibration sources 132a, 132b, 132c, and 132d. The first group vibration sources 130a, 130b, 130c, and 130d may include at least one pair of vibration sources arranged to face each other on at least one long axis. According to an embodiment, a pair of second group vibration sources 132a and 132c are arranged on a first long axis 420a, and another pair of second group vibration sources 132b and 132d are arranged on a second long axis 420b. Also, a pair of first group vibration sources 130a and 130c are arranged on a first short axis 410a, and another pair of first group vibration sources 130b and 130d are arranged on a second short axis 410b. The first short axis 410a, the first long axis 420a, the second short axis 410b, and the second long axis 420b may be arranged at a 45° angle with adjacent axes in the described order.

According to an embodiment, a pair of vibration sources 130 are arranged in opposite positions, and by arranging the vibration sources 130 in the plurality of concentric circles 134 and 136, the first group vibration sources 130a, 130b, 130c, and 130d of the short axes 410a and 410b between the second group vibration sources 132a, 132b, 132c, and 132d of the long axes 420a and 420b may serve as springs. Due to this, the device transfer apparatus 100 may form a reflected wave in a region rotated by 20 degrees to 90 degrees by vibration energies output from the vibration sources 130. Also, the reflected wave formed in this way forms a composite vector in an acoustic potential field over time, and as a result, a dispersion pattern of the micro devices 330 changes periodically. Also, in order to induce a torque generation, a beat frequency of 1 to 10 Hz is additionally applied, and thereby, dispersion of the micro devices 330 may be induced more quickly. The beat frequency represents a frequency difference between other vibration sources or a frequency difference over time in a vibration output sequence of the vibration sources 130. By applying the beat frequency, the vibration energy output from the plurality of vibration sources 130 appears as a synthesized waveform, a swing effect is obtained as much as a width of a wavelength difference according to a frequency difference between two vibrations, and accordingly, a force field that may further accelerate probabilistically the dispersion of the micro devices 330 may be provided. When vibration energy is applied to a fluid in the container 120 from the plurality of vibration sources 130, a total acoustical pressure is represented by Equation 1.

$$P ( x \text{?} t ) = {P}_{0} cos ( {ω}_{2} t + \frac{{ω}_{2}}{{c}_{0}} x ) + {P}_{0} cos ( {ω}_{\text{?}} t + \frac{{ω}_{1}}{{c}_{0}} x ) \qquad Equation 1$$

$$\text{?} \text{indicates text missing or illegible when filed}$$

In Equation 1, P₀ is a wave amplitude, an angular velocity ω₁ is 2πf₁ (rad/s), an angular velocity ω₂ is 2π*f₂ (rad/s), t(s) is time, x(m)ᵢ is a distance from a vibration source 130, and c₀ refers to a sound wave propagation speed in a medium. Here, f₁=f₂+Δf, and Δf refers to a beat frequency.

In Equation 1, when the sound wave propagation speed of a medium is ω₁=ω₂+ε and ω=(ω₁+ω₂)/2, the force field applied to all of the micro devices 330 is represented by Equation 2.

$${\text{?}}_{\text{?}} ( x , t ) = 4 π k {r}^{\text{?}} ( \frac{{P}_{D}^{2}}{4 {ρ}_{0} {c}_{0}^{2}} ) Φ ( ρ , c ) sin ( 2 k \text{?} - \text{?} t ) \qquad Equation 2$$

$$\text{?} \text{indicates text missing or illegible when filed}$$

Here, r is a radius of the micro device 330 (m), ρ₀ is density of a fluid (kg/m³), ρ is density of the micro device 330 (kg/m³), c is a sound speed in the micro device 330, ϕ(ρ,c) is an acoustic contrast factor, and k=ω/c₀ refers to a wave number (m⁻¹). PD is an acoustic pressure field and may correspond to 2P_{O}. P_{O} corresponds to an average peak amplitude of two waves with a beat frequency. A force field moves from a high-frequency vibration source to a low-frequency vibration source at a constant speed v=ε/2 k in units of m/s. When frequencies of excitation are given as f₁=f₂+Δf and f=(f₁+f₂)/2 (Hz), the speed of a vibration pattern is v=(Δf/2f)c₀.

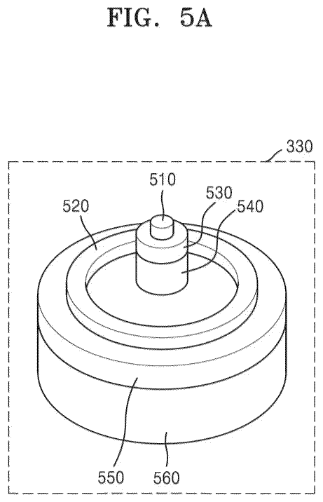

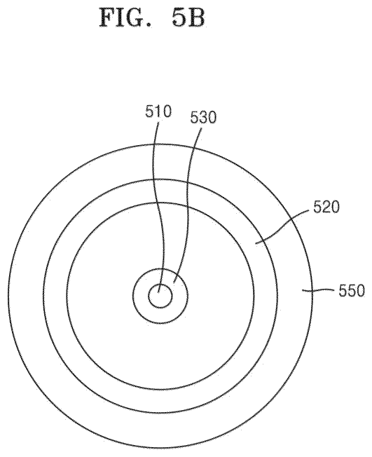

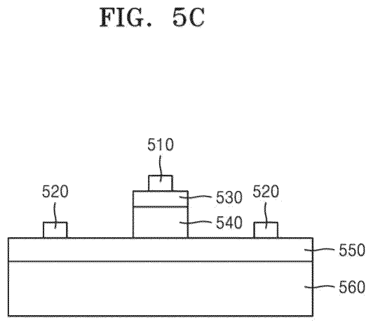

FIGS. 5A, 5B, and 5C are views illustrating a structure of a micro device according to an embodiment. FIG. 5A is a perspective view of the micro device, FIG. 5B is a top view of the micro device, and FIG. 5C is a cross-sectional view of the micro device.

According to one embodiment, the micro device 330 may correspond to a micro LED chip. The micro device 330 according to an embodiment may have a left-right symmetrical shape and a vertically asymmetrical shape. The micro device 330 may include a first electrode 510 and a second electrode 520, and a lower surface, which is opposite to an upper surface on which the first electrode 510 and the second electrode 520 are formed, is inserted into the device hole 320 of the substrate 310, and accordingly, the micro device 33 may be safely placed in the device hole 320.

The micro device 330 may further include a first layer 530, a second layer 540, a third layer 550, and a fourth layer 560. The first electrode 510 may have a cylindrical shape having a diameter of about 5 mm. The second electrode 520 may have a ring shape having a thickness of about 5 mm and may be on the third layer 550. The first layer 530 and the second layer 540 may each have a cylindrical shape having a diameter of 10 mm. The third layer 550 and the fourth layer 560 may each have a cylindrical shape having a diameter of 40 mm.

In a state where the micro devices 330 are distributed in a fluid in the container 120, the device transfer apparatus 100 may move the micro device 330 from some vibration sources 130 selected from among the plurality of vibration sources 130 by outputting a preset output frequency. The micro device 330 may be moved within the fluid by vibration energy and be transferred to the substrate 312 when the fourth layer 560 is inserted into the device hole 320.

According to an embodiment, various shapes of micro devices 330, chips, and so on may be transferred onto the substrate 312 by using the device transfer apparatus 100, in addition to the micro devices 330 illustrated in FIGS. 5A, 5B, and 5C.

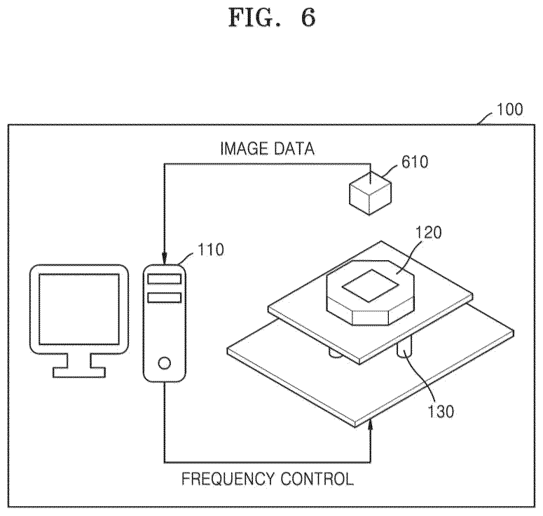

FIG. 6 is a diagram illustrating a structure of a device transfer apparatus according to an embodiment.

According to the embodiment, the device transfer apparatus 100 may include a computing device 110, a container 120, a plurality of vibration sources 130, and a camera 610. The computing device 110 includes a processor 210 that controls the device transfer apparatus 100.

The camera 610 generates an electrical image signal by photoelectrically converting incident light. The camera 610 may include at least one lens, a lens driver, and an image sensor. The camera 610 may include a plurality of cameras 610. The camera 610 generates captured image data and outputs the captured image data to the processor 210.

The camera 610 may image an upper surface of the substrate 312 in the container 120. The camera 610 may be fixed at a preset position to face an upper surface of the container 120. The camera 610 may be arranged such that a field of view (FOV) may be adjusted, that is, an imaging direction may be adjusted. The camera 610 may capture a still image or video based on a control signal output from the processor 210. The camera 610 may transmit the captured image to the computing device 100.

The processor 210 receives an image captured by the camera 610. The processor 210 determines a transfer state of the micro device 330 transferred onto the substrate 312 by using the captured image. The transfer state refers to a ratio of the device holes 320 into which the micro devices 330 are transferred to all the device holes 320 of the substrate 312. The processor 210 recognizes the device holes 320 from the captured image and determines whether the micro devices 330 are transferred into the device holes 320. The processor 210 may recognize the device holes 320 by using a preset image recognition algorithm and determine whether the micro devices 330 are completely transferred into the respective device holes 320. According to an embodiment, the computing device 110 may store information on the number and arrangement of the device holes 320 in advance in a preset memory, and the processor 210 may identify the device holes 320 by using the previously stored information The processor 210 calculates a ratio of device holes 320 into which transfer is completed to all the device holes 320 by using the number of device holes 320 into which transfer is completed, thereby checking a transfer state.

According to one embodiment, the processor 210 recognizes the other micro devices 330 of which transfer are not completed, from the captured image. The processor 210 may obtain position information and distribution information of the other micro devices 330. The processor 210 may cause the plurality of vibration sources 130 to output vibration from to transfer the other micro devices 330 into empty device holes 320.

According to an embodiment, the device transfer apparatus 100 may control the plurality of vibration sources 130 by using a plurality of operation modes that define operations of the plurality of vibration sources 130. The plurality of operation modes may define whether the plurality of vibration sources 130 operate, output frequencies of the plurality of vibration sources 130, output cycles thereof, and output times thereof. The device transfer apparatus 100 may move the micro devices 330 in a desired direction or pattern by using the plurality of operation modes. The plurality of operation modes are described in detail below.

According to one embodiment, the device transfer apparatus 100 includes at least one connection plate (not illustrated) between the plurality of vibration sources 130 and the container 120. According to one embodiment, the at least one connection plate may include eight connection plates (not illustrated) to individually connect the plurality of vibration sources 130 to the container 120. Also, according to an embodiment, the at least one connection plate may be implemented by one plate that comes into contact with the plurality of vibration sources 130.

According to an embodiment, the processor 210 determines an operation mode based on the transfer state and the distribution of the other micro devices 330 obtained from the captured image. According to an embodiment, the processor 210 may control the movement of the other micro devices 330 according to an operation mode sequence in which the plurality of operation modes are sequentially performed.

The device transfer apparatus 100 may repeat operations of capturing an image, determining a transfer state of the substrate 312, and then determining and performing an operation mode until reaching a target transfer rate. The target transfer rate may be a predefined value, for example, 99.5% or so on.

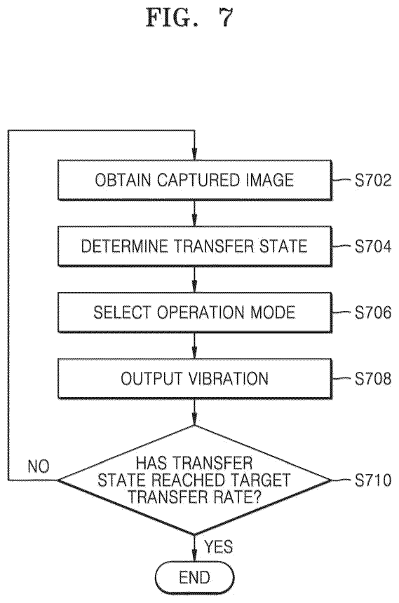

FIG. 7 is a diagram illustrating a method of controlling a device transfer apparatus, according to an embodiment.

According to the embodiment, the method of controlling a device transfer apparatus may be performed by the device transfer apparatus 100 according to an embodiment. Also, the method of controlling a device transfer apparatus, according to an embodiment, may be performed by a preset electronic device (for example, a desktop PC, a laptop PC, a tablet PC, a communication terminal, or so on) including a processor and memory. Although the disclosure provides an embodiment in which the method of controlling a device transfer apparatus is performed by the device transfer apparatus 100 according to an embodiment, but the embodiment is not limited thereto.

In operation S702, the device transfer apparatus 100 captures an image of the substrate 312 in the container 120 by using the camera 610 to obtain an image. The captured image may be an image obtained by capturing an image of an upper surface of the substrate 312.

Next, in operation S704, the device transfer apparatus 100 determines a transfer state of the substrate 312 by using the captured image. The device transfer apparatus 100 may determine the transfer state of the substrate 312 by calculating a ratio of micro devices 330 which are completely transferred into the device holes 320 formed in the substrate 312. Also, according to an embodiment, the device transfer apparatus 100 may detect the remaining micro devices 330 in a fluid of the container 120 by using the captured image. The device transfer apparatus 100 may identify positions or distribution of the remaining micro devices 330.

Also, according to an embodiment, the device transfer apparatus 100 may detect remaining device holes into which the micro devices 330 are not transferred among the plurality of device holes 320 of the substrate 312 by using the captured image. The device transfer apparatus 100 may detect at least one of the plurality of device holes 320 into which the micro devices 330 are completely transferred or at least one of device holes into which the micro devices 330 are not transferred, from the captured image. The device transfer apparatus 100 may classify the plurality of device holes 320 into transfer-completed device holes and the remaining device holes according to the detection result. The device transfer apparatus 100 may identify positions or distribution of the remaining device holes.

Next, in operation S706, the device transfer apparatus 100 may select an operation mode of the plurality of vibration sources 130 based on a transfer state of the substrate 312 and the positions of the remaining micro devices 330. The device transfer apparatus 100 may determine a target position to move the remaining micro devices based on the transfer state and the positions of the remaining micro devices and select an operation mode for moving the remaining micro devices to the target position.

According to an embodiment, the device transfer apparatus 100 may select an operation mode based on the transfer state, the positions of the remaining micro devices, and the positions of the remaining device holes. The device transfer apparatus 100 may set a target position to move the remaining micro devices based on the positions of the remaining micro devices and the positions of the remaining device holes. The device transfer apparatus 100 may select an operation mode based on the current positions of the remaining micro devices and the target position to which the remaining micro devices are to be moved.

According to an embodiment, the device transfer apparatus 100 may select an operation mode by using an artificial intelligence (AI) model. The device transfer apparatus 100 may input a captured image to the AI model, and the AI model may output a selected operation mode based on the captured image. The AI model may be machine-learned by training data including multiple captured images and operation modes. According to an embodiment, the AI model may use a proximal policy optimization (PPO) algorithm. Also, according to an embodiment, at least one of trust region policy optimization (TRPO), advantage actor critic (A2C), and deep q network (DQN) may be used.

Next, in operation S708, the device transfer apparatus 100 controls the plurality of vibration sources 130 in the selected operation mode to output vibrations from the plurality of vibration sources 130. The processor 210 controls the plurality of vibration sources 130 in a manner defined in the selected operation mode. The processor 210 generates a drive signal with an output frequency defined in the selected operation mode and outputs the generated drive signal to the vibration source 130 that outputs the vibration. The processor 210 controls the plurality of vibration sources 130 to output vibrations in a set pattern for a preset time or cycle.

When vibrations are output from the plurality of vibration sources 130, the vibrations are transferred from the plurality of vibration sources 130 to the container 120 through the connection plates and transferred to a fluid in the container 120, thereby inducing a wave in the fluid. The micro device 330 in the fluid is moved due to the wave induced in the fluid. The operation of outputting the vibrations from the plurality of vibration sources 130 is performed for a preset time.

Next, in operation S710, the device transfer apparatus 100 determines whether the transfer state of the substrate 312 reaches the target transfer rate. After the vibrations are completely output in operation S708, the device transfer apparatus 100 may obtain again a captured image of the substrate 312 and determine whether the transfer state of the substrate 312 reaches the target transfer rate based on the captured image.

When the transfer state of the substrate 312 does not reach the target transfer rate, the device transfer apparatus 100 repeats operations S702, S704, S706, and S708. The device transfer apparatus 100 may repeat operations S702, S704, S706, S708, and S710 until the transfer state reaches the target transfer rate.

When the device transfer apparatus 100 determines that the transfer state of the substrate 312 reaches the target transfer rate in operation S710, the processing ends the operations. According to an embodiment, when it is determined that the transfer state of the substrate 312 reaches the target transfer rate, the device transfer apparatus 100 may output a notification that the transfer state reaches the target transfer rate through a preset output interface or an external device.

Next, a plurality of operation modes are described.

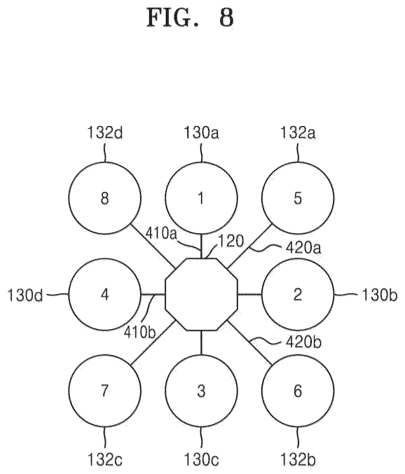

FIG. 8 is a diagram illustrating an arrangement of a plurality of vibration sources according to an embodiment.

According to the embodiment, the plurality of vibration sources 130 may be arranged as illustrated in FIG. 8. The plurality of vibration sources 130 include first group vibration sources 130a, 130b, 130c, and 130d and second group vibration sources 132a, 132b, 132c, and 132d.

The first group vibration sources 130a, 130b, 130c, and 130d) include a first vibration source 130a, a second vibration source 130b, a third vibration source 130c, and a fourth vibration source 130d. The first vibration source 130a and the third vibration source 130c are a pair of vibration sources arranged to face each other on the first short axis 410a. The first vibration source 130a and the third vibration source 130c are arranged at the same distance from the center of a concentric circle on which the plurality of vibration sources 130 are arranged. The second vibration source 130b and the fourth vibration source 130d are a pair of vibration sources arranged to face each other on the second short axis 410b. The second vibration source 130b and the fourth vibration source 130d are arranged at the same distance from the center of the concentric circle on which the plurality of vibration sources 130 are arranged.

The second group vibration sources 132a, 132b, 132c, and 132d includes a fifth vibration source 132a, a sixth vibration source 132b, a seventh vibration source 132c, and an eighth vibration source 132d. The fifth vibration source 132a and the seventh vibration source 132c are a pair of vibration sources arranged to face each other on the first long axis 420a. The fifth vibration source 132a and the seventh vibration source 132c are arranged at the same distance from the center of the concentric circle on which the plurality of vibration sources 130 are arranged. The sixth vibration source 132b and the eighth vibration source 132d are a pair of vibration sources arranged to face each other on the second long axis 420b. The sixth vibration source 132b and the eighth vibration source 132d are arranged at the same distance from the center of the concentric circle on which the plurality of vibration sources 130 are arranged.

In an embodiment, a plurality of operation modes are defined based on the arrangement of the plurality of vibration sources 130 illustrated in FIG. 8.

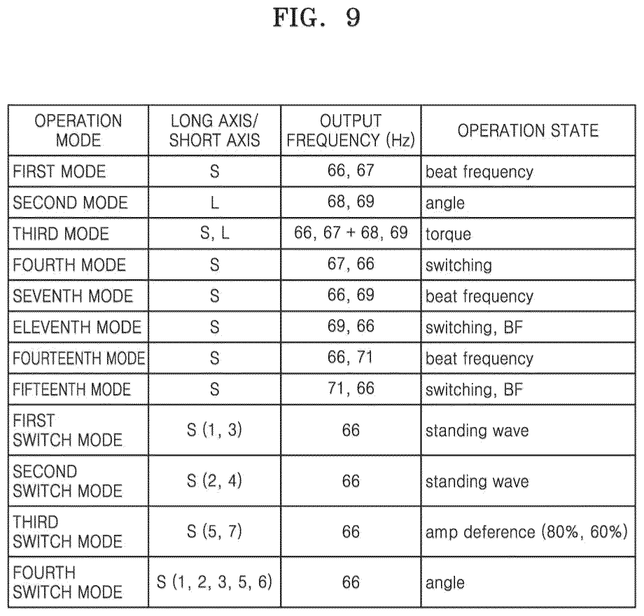

FIG. 9 is a diagram illustrating definitions of a plurality of operation modes according to an embodiment.

According to the embodiment, the plurality of operation modes may be defined by vibration sources that output vibrations in each operation mode and output frequencies. The plurality of operation modes may be defined as illustrated in FIG. 9 and stored in advance in a memory of the device transfer apparatus 100.

The plurality of operation modes may include at least one or a combination of a first mode, a second mode, a third mode, a fourth mode, a seventh mode, an eleventh mode, a fourteenth mode, a fifteenth mode, a first switch mode, a second switch mode, a third switch mode, and a fourth switch mode.

The first mode is a mode in which the first vibration source 130a and the third vibration source 130c, which are a pair of vibration sources on the first short axis 410a, vibrate at a first frequency, and the second vibration source 130b and the fourth vibration source 130d, which are a pair of vibration sources on the second short axis 410b, vibrate at a second frequency that is higher than the first frequency by a first beat frequency. For example, the first frequency may be 66 Hz, the second frequency may be 67 Hz, and the first beat frequency may be 1 Hz. The first mode is an operation mode in which a beat frequency is applied to a fluid in the container 120.

The second mode is a mode in which the fifth vibration source 132a and the seventh vibration source 132c, which are a pair of vibration sources on the first long axis 420a, vibrate at a third frequency, and the sixth vibration source 132b and the eighth vibration source 132d, which are a pair of vibration sources on the second long axis 420b, vibrate at a fourth frequency that is higher than the third frequency by the first beat frequency. For example, the third frequency may be 68 Hz, the fourth frequency may be 69 Hz, and the first beat frequency may be 1 Hz.

The third mode is a mode in which the first vibration source 130a and the third vibration source 130c, which are a pair of vibration sources on the first short axis 410a, vibrate at the first frequency, the second vibration source 130b and the fourth vibration source 130d, which are a pair of vibration sources on the second short axis 410b, vibrate at the second frequency, the fifth vibration source 132a and the seventh vibration source 132c, which are a pair of vibration sources on the first long axis 420a, vibrate at the third frequency, and the sixth vibration source 132b and the eighth vibration source 132d, which are a pair of vibration sources on the second long axis 420b, vibrate at the fourth frequency.

The third mode is an operation mode in which torque is applied to a fluid in the container 120. In the third mode, by operating all of the plurality of vibration sources 130, a distribution pattern rotates over time.

The fourth mode is an operation mode in which the pair of vibration sources on the first short axis 410a vibrate at the second frequency, and the pair of vibration sources on the second short axis 410b vibrate at the first frequency. The fourth mode is an operation mode in which an output frequency of the first mode is switched between the pair of vibration sources on the first short axis 410a and the pair of vibration sources on the second short axis 410b to apply a beat frequency to a fluid in the container 120.

The seventh mode is an operation mode in which the pair of vibration sources on the first short axis 410a vibrate at the first frequency and the pair of vibration sources on the second short axis 410b vibrate at a fifth frequency that is higher than the first frequency by a second beat frequency. For example, the second bit frequency may be 3 Hz, and the fifth frequency may be 69 Hz. The seventh mode is an operation mode in which a beat frequency is applied to a fluid in the container 120.

The eleventh mode is an operation mode in which the pair of vibration sources on the first short axis 410a vibrate at the fifth frequency and the pair of vibration sources on the second short axis 410b vibrate at the first frequency. The eleventh mode is an operation mode in which an output frequency of the seventh mode is switched between the pair of vibration sources on the first short axis 410a and the pair vibration sources on the second short axis 410b to apply a beat frequency to a fluid in the container 120.

The fourteenth mode is an operation mode in which the pair of vibration sources on the first short axis 410a vibrate at the first frequency and the pair of vibration sources on the second short axis 410b vibrate at a sixth frequency that is higher than the first frequency by a third beat frequency. For example, the third bit frequency may be 5 Hz, and the sixth frequency may be 71 Hz. The fourteenth mode is an operation mode in which a beat frequency is applied to a fluid in the container 120.

The fifteenth mode is an operation mode in which the pair of vibration sources on the first short axis 410a vibrate at the sixth frequency and the pair of vibration sources on the second short axis 410b vibrate at the first frequency. The fifteenth mode is an operation mode in which an output frequency of the fourteenth mode is switched between the pair of vibration sources on the first short axis 410a and the pair of vibration sources on the second short axis 410b to apply a beat frequency to a fluid in the container 120.

The first switch mode is an operation mode in which the pair of vibration sources on the first short axis 410a vibrate at the first frequency. In the first switch mode, a standing wave of a first frequency is generated between the pair of vibration sources on the first short axis 410a.

The second switch mode is an operation mode in which the pair of vibration sources on the second short axis 410b vibrate at the first frequency. In the second switch mode, a standing wave of the first frequency is generated between the pair of vibration sources on the second short axis 410b.

The third switch mode is an operation mode in which the pair of vibration sources on the first long axis 420a vibrate at the first frequency and different signal amplification rates are set between two vibration sources of the pair of vibration sources on the first long axis 420a. For example, the fifth vibration source 132a may output vibration of the first frequency at an amplification rate of 80%, and the seventh vibration source 132c may output vibration of the first frequency at an amplification rate of 60%.

The fourth switch mode is an operation mode in which the pair of vibration sources on the first short axis 410a, and a vibration source in one group of the third group vibration sources and the fourth group vibration sources divided by the first short axis 410a vibrates at the first frequency. For example, the third group vibration sources may include the fourth vibration source 130d, the seventh vibration source 132c, and the eighth vibration source 132d, and the fourth group vibration sources may include the second vibration source 130b, the fifth vibration source 132a, and the sixth vibration source 132b. According to an embodiment, the fourth switch mode may be an operation mode in which the pair of vibration sources on the first short axis 410a and the fourth group vibration sources vibrate at the first frequency. That is, the fourth switch mode is a mode in which the first vibration source 130a, the second vibration source 130b, the third vibration source 130c, the fifth vibration source 132a, and the sixth vibration source 132b vibrate at the frequency.

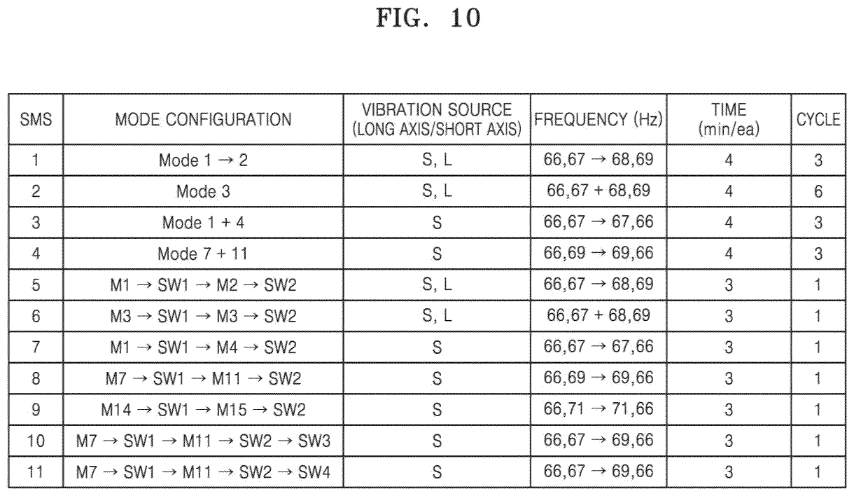

FIG. 10 is a diagram illustrating a plurality of operation modes according to an embodiment.

According to an embodiment, an operation mode may be defined as a sequence of the plurality of operation modes described in FIG. 9. In the disclosure, the operation mode defined as the sequence of operation modes is referred to as a sequential mode shift (SMS) mode.

According to an embodiment, the SMS mode may include a first SMS mode, a second SMS mode, a third SMS mode, a fourth SMS mode, a fifth SMS mode, a sixth SMS mode, a seventh SMS mode, an eighth SMS mode, a ninth SMS mode, a tenth SMS mode, and an eleventh SMS mode. The first to eleventh SMS modes may be defined by the type and order of an operation mode that is performed, an execution time of one cycle, and the number of cycle repetitions.

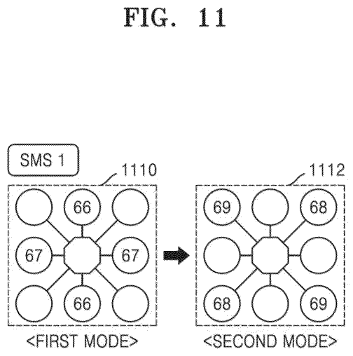

FIGS. 11 to 21 are diagrams illustrating operations of the first to eleventh SMS modes. A plurality of SMS modes are described with reference to FIGS. 10 to 21. Respective circles in FIGS. 11 to 21 refer to the vibration sources 130, and an octagon refers to the container 120. Also, arrangements of the vibration sources 130 in FIGS. 11 to 21 correspond to the arrangement of the vibration sources 130 described in FIG. 8. Numbers written in the circles corresponding to the vibration sources 130 indicate output frequencies in units of Hz, and empty circles indicate a state in which vibration is not output.

FIG. 11 is a diagram illustrating an operation of the first SMS mode according to an embodiment.

The first SMS mode is an operation mode in which the device transfer apparatus 100 operates in a first mode 1110 and then operates in a second mode 1112. In the first SMS mode, the device transfer apparatus 100 may operate in the first mode 1110 for 4 minutes and then operate in the second mode 1112 for 4 minutes. Also, in the first SMS mode, the device transfer apparatus 100 may repeat a cycle of operation in the first mode 1110 and the second mode 1112 thrice.

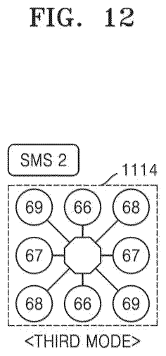

FIG. 12 is a diagram illustrating an operation of the second SMS mode according to an embodiment.

The second SMS mode is an operation mode in which the device transfer apparatus 100 operates in a third mode 1114. In the second SMS mode, the device transfer apparatus 100 may repeat six times a cycle of operation for 4 minutes in the third mode 1114.

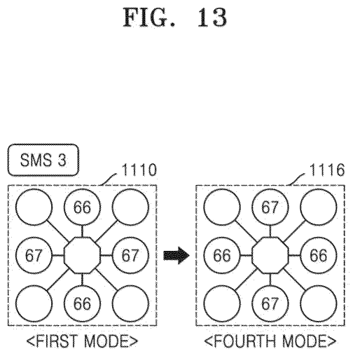

FIG. 13 is a diagram illustrating an operation of the third SMS mode according to an embodiment.

The third SMS mode is an operation mode in which the device transfer apparatus 100 operates in the first mode 1110 and then operates in a fourth mode 1116. In the third SMS mode, the device transfer apparatus 100 may operate in the first mode 1110 for 4 minutes and then operate in the fourth mode 1116 for 4 minutes. Also, in the third SMS mode, the device transfer apparatus 100 may repeat a cycle of operation in the first mode 1110 and the fourth mode 1116 three times thrice.

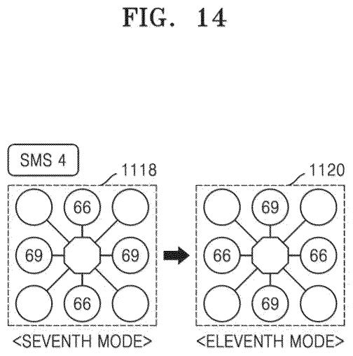

FIG. 14 is a diagram illustrating an operation of the fourth SMS mode according to an embodiment.

The fourth SMS mode is an operation mode in which the device transfer apparatus 100 operates in a seventh mode 1118 and then operates in an eleventh mode 1120. In the fourth SMS mode, the device transfer apparatus 100 may operate in the seventh mode 1118 for 4 minutes and then operate in the eleventh mode 1120 for 4 minutes. Also, in the fourth SMS mode, the device transfer apparatus 100 may repeat a cycle of operation in the seventh mode 1118 and the eleventh mode 1120 thrice.

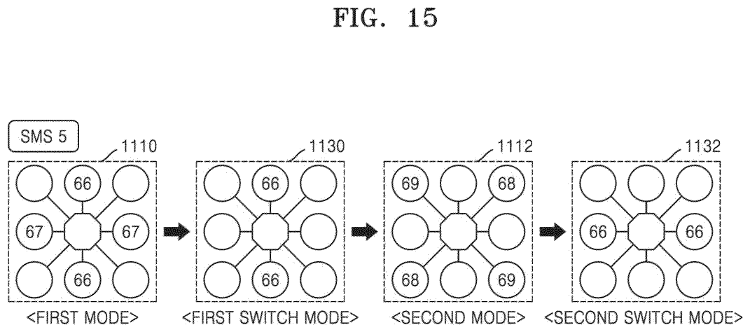

FIG. 15 is a diagram illustrating an operation of the fifth SMS mode according to an embodiment.

The fifth SMS mode is an operation mode in which the device transfer apparatus 100 sequentially operates in the first mode 1110, a first switch mode 1130, the second mode 1112, and a second switch mode 1132. In the fifth SMS mode, the device transfer apparatus 100 may operate in the first mode 1110 for 3 minutes, operate in the first switch mode 1130 for 3 minutes, operate in the second mode 1112 for 3 minutes, and then operate in the second switch mode 1132 for 3 minutes. Also, in the fifth SMS mode, the device transfer apparatus 100 may perform one cycle of operation in the first mode 1110, the first switch mode 1130, the second mode 1112, and the second switch mode 1132.

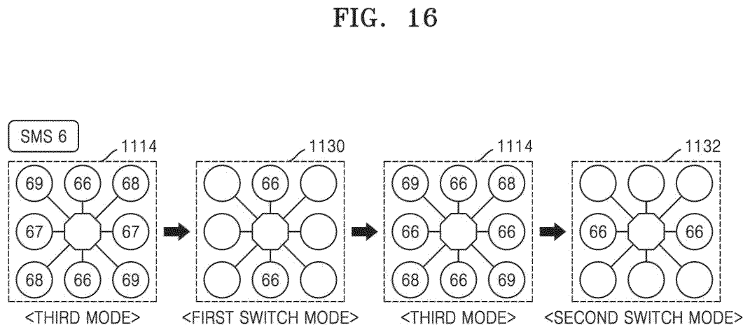

FIG. 16 is a diagram illustrating an operation of the sixth SMS mode according to an embodiment.

The sixth SMS mode is an operation mode in which the device transfer apparatus 100 sequentially operates in the third mode 1114, the first switch mode 1130, the third mode 1114, and the second switch mode 1132. In the sixth SMS mode, the device transfer apparatus 100 may operate in the third mode 1114 for 3 minutes, operate in the first switch mode 1130 for 3 minutes, operate in the third mode 1114 for 3 minutes, and then operate in the second switch mode 1132 for 3 minutes. Also, in the sixth SMS mode, the device transfer apparatus 100 may perform one cycle of operation in the third mode 1114, the first switch mode 1130, the third mode 1114, and the second switch mode 1132.

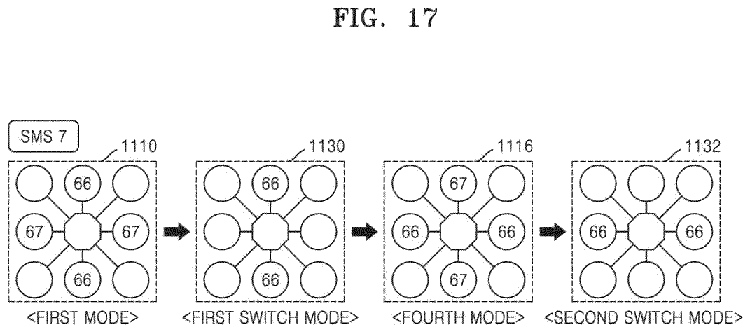

FIG. 17 is a diagram illustrating an operation of the seventh SMS mode according to an embodiment.

The seventh SMS mode is an operation mode in which the device transfer apparatus 100 sequentially operates in the first mode 1110, the first switch mode 1130, the fourth mode 1116, and the second switch mode 1132. In the seventh SMS mode, the device transfer apparatus 100 may operate in the first mode 1110 for 3 minutes, operate in the first switch mode 1130 for 3 minutes, operate in the fourth mode 1116 for 3 minutes, and then operate in the second switch mode 1116 for 3 minutes. Also, in the seventh SMS mode, the device transfer apparatus 100 may perform one cycle of operation in the first mode 1110, the first switch mode 1130, the fourth mode 1116, and the second switch mode 1132.

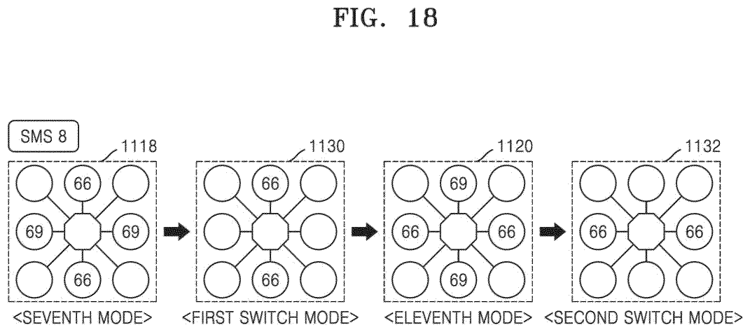

FIG. 18 is a diagram illustrating an operation of the eighth SMS mode according to an embodiment.

The eighth SMS mode is an operation mode in which the device transfer apparatus 100 sequentially operates in the seventh mode 1118, the first switch mode 1130, the eleventh mode 1120, and the second switch mode 1132. In the eighth SMS mode, the device transfer apparatus 100 may operate in the seventh mode 1118 for 3 minutes, operate in the first switch mode 1130 for 3 minutes, operate in the eleventh mode 1120 for 3 minutes, and then operate in the second switch mode 1132 for 3 minutes. Also, in the eighth SMS mode, the device transfer apparatus 100 may perform one cycle of operation in the seventh mode 1118, the first switch mode 1130, the eleventh mode 1120, and the second switch mode 1132.

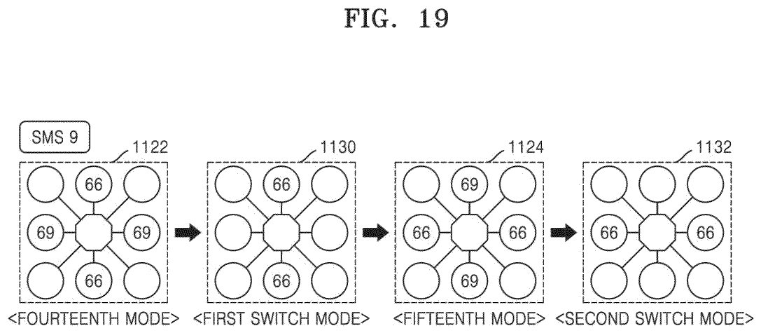

FIG. 19 is a diagram illustrating an operation of the ninth SMS mode according to an embodiment.

The ninth SMS mode is an operation mode in which the device transfer apparatus 100 sequentially operates in a fourteenth mode 1122, the first switch mode 1130, a fifteenth mode 1124, and the second switch mode 1132. In the ninth SMS mode, the device transfer apparatus 100 may operate in the fourteenth mode 1122 for 3 minutes, operate in the first switch mode 1130 for 3 minutes, operate in the fifteenth mode 1124 for 3 minutes, and then operate in the second switch mode 1132 for 3 minutes. Also, in the ninth SMS mode, the device transfer apparatus 100 may perform one cycle of operation in the fourteenth mode 1122, the first switch mode 1130, the fifteenth mode 1124, and the second switch mode 1132.

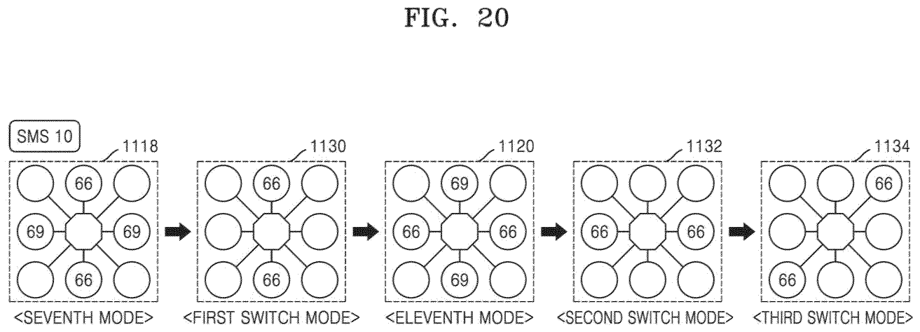

FIG. 20 is a diagram illustrating an operation of the tenth SMS mode according to an embodiment.

The tenth SMS mode is an operation mode in which the device transfer apparatus 100 sequentially operates in the seventh mode 1118, the first switch mode 1130, the eleventh mode 1120, the second switch mode 1132, and a third switch mode 1134. In the tenth SMS mode, the device transfer apparatus 100 may operate in the seventh mode 1118 for 3 minutes, operate in the first switch mode 1130 for 3 minutes, operate in the eleventh mode 1120 for 3 minutes, operate in the second switch mode 1132 for 3 minutes, and then operate in the third switch mode 1134 for 3 minutes. Also, in the tenth SMS mode, the device transfer apparatus 100 may perform one cycle of operation in the seventh mode 1118, the first switch mode 1130, the eleventh mode 1120, the second switch mode 1132, and the third switch mode 1134.

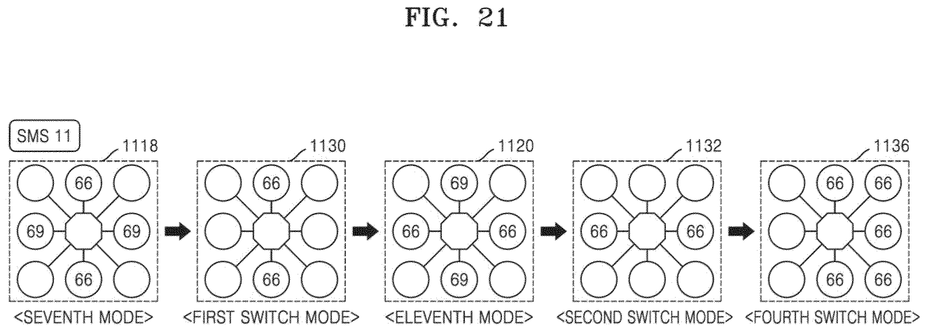

FIG. 21 is a diagram illustrating an operation of the eleventh SMS mode according to an embodiment.

The eleventh SMS mode is an operation mode in which the device transfer apparatus 100 sequentially operates in the seventh mode 1118, the first switch mode 1130, the eleventh mode 1120, the second switch mode 1132, and a fourth switch mode 1136. In the eleventh SMS mode, the device transfer apparatus 100 may operate in the seventh mode 1118 for 3 minutes, operate in the first switch mode 1130 for 3 minutes, operate in the eleventh mode 1120 for 3 minutes, and operate in the second switch mode 1132 for 3 minutes, and then in the fourth switch mode 1136 for 3 minutes. Also, in the eleventh SMS mode, the device transfer apparatus 100 may perform one cycle of operation in the seventh mode 1118, the first switch mode 1130, the eleventh mode 1129, the second switch mode 1132, and the fourth switch mode 1136.

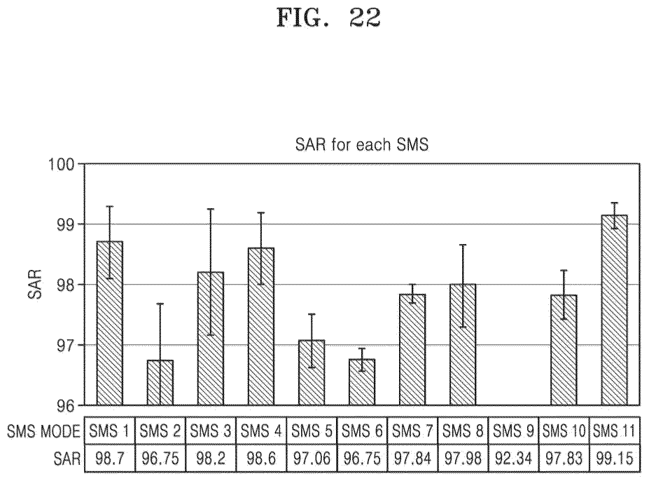

FIG. 22 is a diagram illustrating a self-assembly ratio (SAR) according to an SMS mode according to an embodiment.

After performing the first to eleventh SMS modes according to an embodiment, the SAR was measured. The measurement was made under the following conditions: substrate size 40.7 mm, device hole array 160*160, pitch 181 mm, pattern 45 mm, depth 5 mm, trench width 150 mm, and depth 15 mm. As illustrated in FIG. 22, a self-assembly ratio of 92% or more was observed in the first to eleventh SMS modes. Also, SAR values of 98% or more were measured in the first SMS mode, third SMS mode, and fourth SMS mode, and SAR values of 99% or more were measured in the eleventh SMS mode. In this way, according to the SMS modes of the disclosure, there is a remarkable effect of obtaining a high self-assembly ratio.

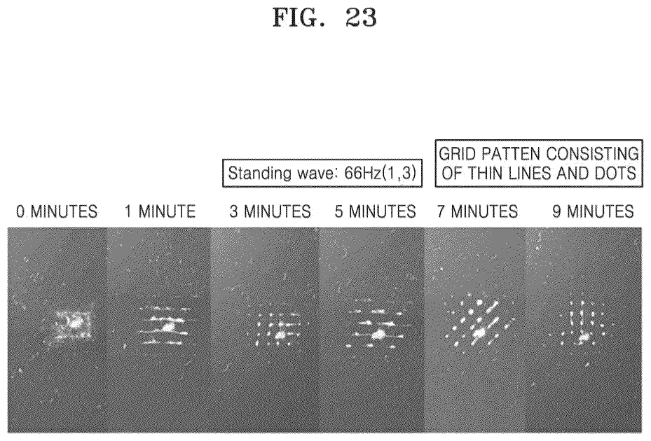

FIG. 23 illustrates images of movement of micro devices captured while applying a standing wave of 66 Hz, according to an embodiment.

FIG. 23 illustrates images of a standing wave of 66 Hz taken at 0 minutes, 1 minute, 3 minutes, 5 minutes, 7 minutes, and 9 minutes while outputting vibration of 66 Hz from the first vibration source 130a and the third vibration source 130c. The operation mode of FIG. 23 may correspond to the first switch mode. As illustrated in FIG. 23, micro devices are arranged irregularly at 0 minutes, but as time passes, the distribution of the micro devices has a grid pattern, and it can be seen that the grid pattern rotates. Also, in FIG. 23, it can be seen that the micro devices form a grid pattern consisting of thin lines and dots.

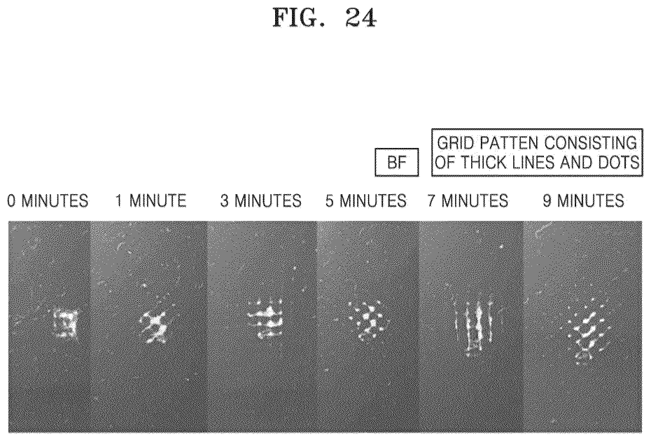

FIG. 24 illustrates images of movement of micro devices captured while applying the first beat frequency, according to an embodiment.

FIG. 24 illustrates images taken at 0 minutes, 1 minute, 3 minutes, 5 minutes, 7 minutes, and 9 minutes while outputting vibration such that output frequencies of the pair of vibration sources on the first short axis 410a and the pair of vibration sources on the second short axis 410b differ by the first beat frequency. The operation mode of FIG. 24 may correspond to the first mode. As illustrated in FIG. 24, the micro devices are arranged irregularly at 0 minutes, but as time passes, the distribution of the micro devices has a grid pattern, and it can be seen that the grid pattern rotates. Also, in FIG. 24, it can be seen that the micro devices form a grid pattern consisting of thicker lines and dots than the grid pattern in FIG. 23.

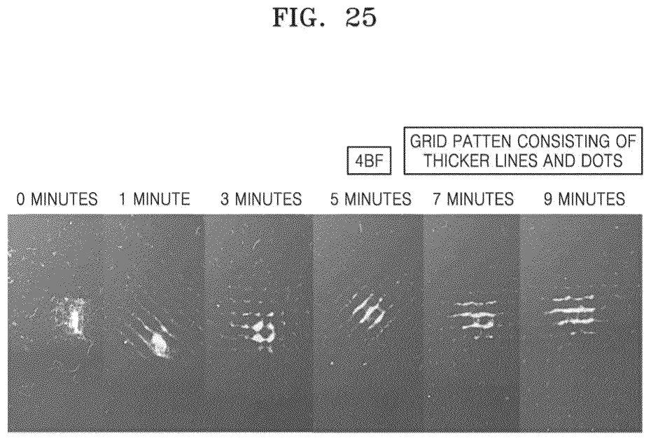

FIG. 25 illustrates images of movement of micro devices captured while applying the second beat frequency, according to an embodiment.

FIG. 25 illustrates images taken at 0 minutes, 1 minute, 3 minutes, 5 minutes, 7 minutes, and 9 minutes while outputting vibration such that output frequencies of the pair of vibration sources on the first short axis 410a and the pair of vibration sources on the second short axis 410b differ by the second beat frequency. The second beat frequency may correspond to 4 times the first beat frequency. As illustrated in FIG. 25, the micro devices are arranged irregularly at 0 minutes, but as time passes, the distribution of the micro devices has a grid pattern, and it can be seen that the grid pattern rotates. Also, in FIG. 25, it can be seen that the micro devices form a grid pattern consisting of thicker lines and dots than the grid pattern in FIG. 24.

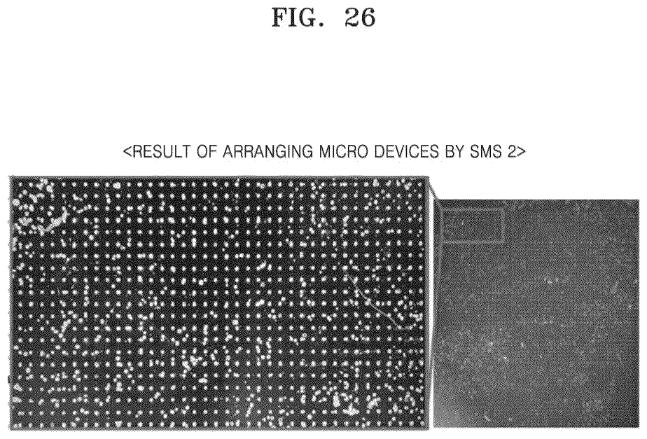

FIG. 26 illustrates captured images of a result of arraying micro devices, according to an embodiment.

FIG. 26 is a microscopic image of micro devices being transferred to a substrate after operating in the second SMS mode. It may be seen in FIG. 26 that a transfer rate of micro devices reaches 99%. It is analyzed that remaining device holes and remaining micro devices that are not transferred are due to transfer interference caused by the natural occurrence of some defective chips, and it is expected that the transfer rate may be increased by improving chip quality control and work environment.

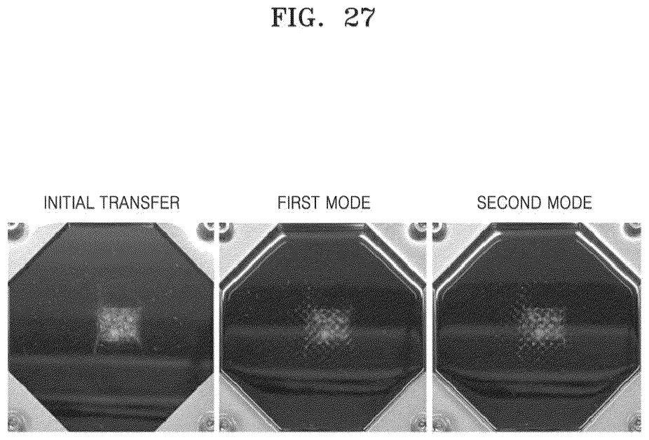

FIG. 27 illustrates images of states in which the first mode and the second mode are sequentially performed, according to an embodiment.

According to the embodiment, micro devices are arranged irregularly at an initial stage of transfer. Thereafter, when a plurality of vibration sources operate in the first mode, the micro devices move in a grid pattern and are transferred to a substrate. Next, when the plurality of vibration sources operate in the second mode, the grid pattern of the micro devices is rearranged into a different grid pattern, causing the micro device to move, and the micro devices are transferred to the remaining device holes.

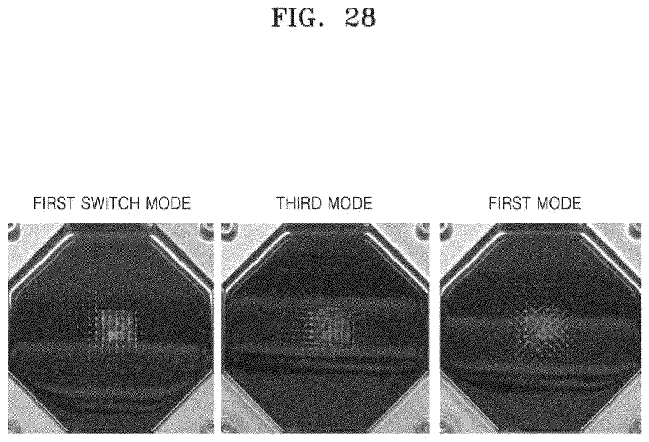

FIG. 28 illustrates images of states in which the first switch mode, the third mode, and the first mode are sequentially performed, according to an embodiment.

According to the embodiment, in the first switch mode, the micro devices are arranged in a grid pattern of thin lines, and the micro devices are transferred. Thereafter, when the plurality of vibration sources operate in the third mode, the micro devices are rearranged into a grid pattern of thick lines, and the micro devices are transferred to the remaining device holes. Next, when the plurality of vibration sources operate in the first mode, the grid pattern of the micro devices is rearranged into a different type of grid pattern, causing the micro devices to move, and the micro devices are transferred to the remaining device holes.

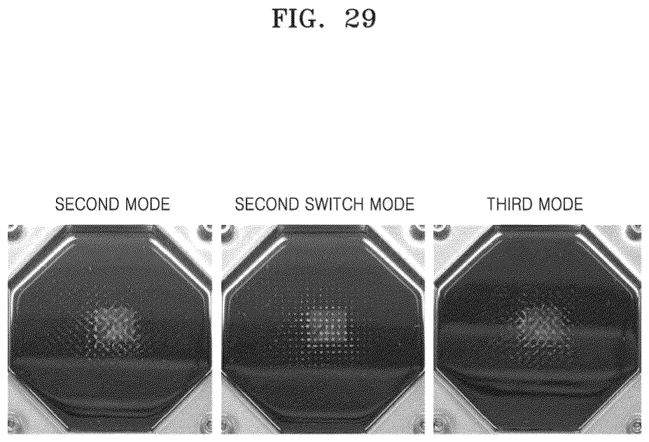

FIG. 29 illustrates images of states in which the second mode, the second switch mode, and the third mode are sequentially performed, according to an embodiment.

According to the embodiment, in the second mode, the micro devices are arranged in a grid pattern, and the micro devices are transferred. Thereafter, when the plurality of vibration sources operate in the second switch mode, the micro devices are rearranged into a different type of grid pattern, and the micro devices are transferred to the remaining device holes. Next, when the plurality of vibration sources operate in the third mode, the grid pattern of the micro devices is rearranged into a different type of grid pattern, causing the micro devices to move, and the micro devices are transferred to the remaining device holes.

As described above, the disclosed embodiments are described with reference to the attached drawings. Those skilled in the art to which the disclosure pertains will understand that the disclosure may be practiced in forms different from the disclosed embodiments without changing the technical idea or essential features of the disclosure. The disclosed embodiments are illustrative and should not be construed as limiting.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A device transfer apparatus comprising:
a container of a polygonal shape configured to contain a substrate including a plurality of device holes;
a plurality of vibration sources configured to generate vibration and transfer the vibration to a fluid in the container; and
a processor configured to control outputs of the plurality of vibration sources,
wherein the plurality of vibration sources include at least one first group vibration source arranged on a circumference of a first circle having a radius of a first distance from a central point, and at least one second group vibration source arranged on a circumference of a second circle which is concentric with the first circle and has a radius of a second distance that is longer than the first distance,
the container is arranged on the central point and contains a fluid and micro devices distributed in the fluid, and
the processor is further configured to control at least one of the at least one first group vibration source and the at least one second group vibration source to output vibration of an output frequency.

2. The device transfer apparatus of claim 1, wherein
the at least one first group vibration source includes at least one pair of first group vibration sources arranged on at least one short axis passing through the central point and facing each other about the central point, and
the at least one second group vibration source includes at least one pair of second group vibration sources arranged on at least one long axis passing through the central point and facing each other about the central point.

3. The device transfer apparatus of claim 2, wherein the at least one short axis and the at least one long axis are arranged alternately at equal angular intervals.

4. The device transfer apparatus of claim 2, wherein
the at least one short axis includes a first short axis and a second short axis, the at least one long axis includes a first long axis and a second long axis, and
the at least one short axis and the at least one long axis are arranged at intervals of 45 degrees in an order of the first short axis, the first long axis, the second short axis, and the second long axis.

5. The device transfer apparatus of claim 4, wherein
the container has an octagonal shape, and
each of the at least one short axis and the at least one long axis is arranged to correspond to each corner of the octagonal shape of the container.

6. The device transfer apparatus of claim 2, wherein
a pair of first group vibration sources facing each other output vibrations of a same frequency, and
a pair of second group vibration sources facing each other output vibrations of a same frequency.

7. The device transfer apparatus of claim 1, wherein
the processor is further configured to obtain a first image of the substrate in the container, and control the plurality of vibration sources in at least one of a plurality of operation modes in which a predefined output frequency is output through at least one vibration source among the plurality of vibration sources, based on the first image.

8. The device transfer apparatus of claim 7, wherein the processor is further configured to control the plurality of vibration sources to sequentially operate in two or more operation modes among the plurality of operation modes.

9. The device transfer apparatus of claim 7, wherein the processor is further configured to determine, based on the first image, a transfer state in which the micro devices are transferred into a plurality of device holes of the substrate and positions of remaining micro devices that are not transferred to the substrate, and control the plurality of vibration sources to operate in at least one operation mode among the plurality of operation modes based on the transfer state and the positions of the remaining micro devices.

10. The device transfer apparatus of claim 7, wherein the processor is further configured to repeat a cycle of controlling the plurality of vibration sources to operate for a reference time in at least one of the plurality of operation modes and obtaining the first image.

11. The device transfer apparatus of claim 10, wherein the processor is further configured to determine a transfer rate, which is a ratio of the plurality of device holes into which the micro devices are transferred, based on the first image, and when the transfer rate reaches a target transfer rate, the processor is further configured to stop the cycle of controlling the plurality of vibration sources and obtaining the first image.

12. The device transfer apparatus of claim 7, wherein the plurality of operation modes include at least one of:
a first mode in which a pair of vibration sources on a first short axis among the at least first group vibration source vibrate at a first frequency and a pair of vibration sources on a second short axis among the at least one first group vibration source vibrate at a second frequency that is higher than the first frequency by a first beat frequency;
a second mode in which a pair of vibration sources on a first long axis among the at least second group vibration source vibrate at a third frequency and a pair of vibration sources on a second long axis among the at least one second group vibration source vibrate at a fourth frequency that is higher than the third frequency by the first beat frequency;
a third mode in which the pair of vibration sources on the first short axis among the at least first group vibration source vibrate at the first frequency, the pair of vibration sources on the second short axis among the at least one first group vibration source vibrate at the second frequency, the pair of vibration sources on the first long axis among the at least second group vibration source vibrate at the third frequency, and the pair of vibration sources on the second long axis among the at least one second group vibration source vibrate at the fourth frequency;
a fourth mode in which the pair of vibration sources on the first short axis among the at least first group vibration source vibrate at the second frequency and the pair of vibration sources on the second short axis among the at least one first group vibration source vibrate at the first frequency;
a seventh mode in which the pair of vibration sources on the first short axis among the at least first group vibration source vibrate at the first frequency and the pair of vibration sources on the second short axis among the at least one first group vibration source vibrate at a fifth frequency that is higher than the first frequency by a second beat frequency;
an eleventh mode in which the pair of vibration sources on the first short axis among the at least first group vibration source vibrate at the fifth frequency and the pair of vibration sources on the second short axis among the at least one first group vibration source vibrate at the first frequency;
a fourteenth mode in which the pair of vibration sources on the first short axis among the at least first group vibration source vibrate at the first frequency and the pair of vibration sources on the second short axis among the at least one first group vibration source vibrate at a sixth frequency that is higher than the first frequency by a third beat frequency;
a fifteenth mode in which the pair of vibration sources on the first short axis among the at least first group vibration source vibrate at the sixth frequency and the pair of vibration sources on the second short axis among the at least one first group vibration source vibrate at the first frequency;
a first switch mode in which the pair of vibration sources on the first short axis among the at least first group vibration source vibrate at the first frequency;
a second switch mode in which the pair of vibration sources on the second short axis among the at least first group vibration source vibrate at the first frequency;
a third switch mode in which the pair of vibration sources on the first long axis among the at least second group vibration source vibrate at the first frequency and a signal amplification rate is set differently between two vibration sources of the pair of vibration sources on the first long axis; and
a fourth switch mode in which the pair of vibration sources on the first short axis among the at least first group vibration source vibrate at the first frequency, and vibration sources in one group among a third group vibration sources and a fourth group vibration sources, which are divided by the first short axis, vibrate at the first frequency,
the second beat frequency is thrice the first beat frequency, and
the third bit frequency is five times the first bit frequency.

13. The device transfer apparatus of claim 12, wherein the plurality of operation modes include at least one of:
a first sequential mode shift (SMS) mode for operating in the first mode and then operating in the second mode;
a second SMS mode for operating in the third mode;
a third SMS mode for operating in the first mode and then operating in the fourth mode;
a fourth SMS mode for operating in the seventh mode and then operating in the eleventh mode;
a fifth SMS mode for operating in an order of the first mode, the first switch mode, the second mode, and the second switch mode;
a sixth SMS mode for operating in an order of the third mode, the first switch mode, the third mode, and the second switch mode;
a seventh SMS mode for operating in an order of the first mode, the first switch mode, the fourth mode, and the second switch mode;
an eighth SMS mode for operating in an order of the seventh mode, the first switch mode, the eleventh mode, and the second switch mode;
a ninth SMS mode for operating in an order of the fourteenth mode, the first switch mode, the fifteenth mode, and the second switch mode;
a tenth SMS mode for operating in an order of the seventh mode, the first switch mode, the eleventh mode, the second switch mode, and the third switch mode; and
an eleventh SMS mode for operating in an order of the seventh mode, the first switch mode, the eleventh mode, the second switch mode, and the fourth switch mode.

14. The device transfer apparatus of claim 12, wherein the first beat frequency, the second beat frequency, and the third beat frequency are each about 1 Hz to about 30 Hz.

15. The device transfer apparatus of claim 1, wherein vibrations generated by the plurality of vibration sources have frequencies in a range of about 20 Hz to about 500 Hz.

16. The device transfer apparatus of claim 1, further comprising a plurality of connection plates respectively connecting the container to the plurality of vibration sources.

17. The device transfer apparatus of claim 16, wherein each of the plurality of connection plates has a length of about 2 cm to about 20 cm.

18. The device transfer apparatus of claim 1, wherein a length difference between the first distance and the second distance is about 3 cm to about 30 cm.

19. The device transfer apparatus of claim 1, further comprising:
a camera configured to capture an image of the substrate in the container,
wherein the processor is further configured to determine a transfer state in which the micro devices are transferred into the plurality of device holes of the substrate, based on an image captured by the camera, and
determine an operation mode of the at least one first group vibration source or the at least one second group vibration source, based on the determined transfer state.

20. A method of controlling a device transfer apparatus, the method comprising:
obtaining a captured image of a substrate in a container of a polygonal shape containing the substrate including a plurality of device holes;
determining a transfer state in which micro devices are transferred into the plurality of device holes of the substrate, based on the captured image;
determining, based on the determined transfer state, an output frequency output from at least one first group vibration source or at least one second group vibration source, which is configured to transfer vibration to a fluid in the container;
outputting the output frequency from at least one of the at least one first group vibration source and the at least one second group vibration source; and
re-obtaining the captured image after the output of the output frequency is completed, and determining whether the transfer state has reached a target transfer rate, based on the re-obtained captured image,
wherein, when the transfer state has not reached the target transfer rate, the determining of the transfer state, the determining of the output frequency, the outputting of the output frequency, and the determining whether the transfer state has reached the target transfer rate are repeated,
the device transfer apparatus includes a plurality of vibration sources configured to generate vibration and transfer the vibration to a fluid in the container, and the plurality of vibration sources include the at least one first group vibration source on a circumference of a first circle having a radius of a first distance from a central point, and the at least one second group vibration source on a circumference of a second circle which has a radius of a second distance that is longer than the first distance and is concentric with the first circle, and
the container is on the central point.
